(19) United States
(12) Patent Application Publication
(10) Pub. No.: US 2007/0007613 A1
(43) Pub. Date: Jan. 11, 2007

(54) Phase change memory with adjustable resistance ratio and fabricating method thereof

(76) Inventors: Wen-Han Wang, Hsinchu (TW); Jiuh-Ming Liang, Hsinchu (TW); Jyi-Tyan Yeh, Hsinchu (TW); Shan-Haw Chiou, Hsinchu (TW)

Correspondence Address: HARNESS, DICKEY & PIERCE, P.L.C., P.O. BOX 8910, RESTON, VA, 20195, US

(21) Appl. No.: 11/240,449

(22) Filed: Oct. 3, 2005

(30) Foreign Application Priority Data
Jul. 8, 2005 (TW) 94123290

(51) Int. Cl. H01L 31/058; H01L 29/06; H01L 29/02; H01L 47/00; G11C 11/00

(52) U.S. Cl. 257/467; 365/163; 257/2; 257/5

(57) ABSTRACT

A phase change memory with adjustable resistance ratio is disclosed, which includes a phase change layer and an interfacial layer formed to be in contact with each other, and at least two electrodes in contact with the phase change layer and the interfacial layer respectively. The contact sections between the two electrodes and the phase change layer and the interfacial layer define a contact area respectively, wherein, the area defined by the contact section between the electrode and the phase change layer is larger than the area defined by the contact section between the electrode and the interfacial layer.

This Non-provisional application claims priority under 35 U.S.C. §119(a) on Patent Application No(s). 094123290 filed in Taiwan, R.O.C. on Jul. 8, 2005, the entire contents of which are hereby incorporated by reference.

### BACKGROUND OF THE INVENTION

1. Field of Invention

The present invention relates to a phase change memory, and particularly to a phase change memory having a functional layer with adjustable resistance ratio.

2. Related Art

Common electronic products usually require combination of various memories, among which the DRAM, SRAM, Flash and the like are the most popular. Recently, several new memory techniques including the FeRAM, MRAM and Phase Change Memory are being developed.

A phase change memory can meet the requirements for rapid mass storage and long term data storage. It does not only have a small volume, and can store more data rapidly, but also can be preserved at 130 for more than ten years. The phase change memory has many advantages, such as non-volatility, high read signal, high density, high erase cycles and low working voltage/current, thus it is a non-volatile memory with high potential. The mainstream of the current research is to pursue a higher record density and lower power consumption by reducing the memory cells.

In some prior arts related to the phase change memory, such as the structure disclosed in the U.S. Pat. No. 6,545,287, after a spacer is produced, an interfacial layer is coated as an adhesion promoting layer before coating the phase change layer, wherein the interfacial layer is only deposited on the bottom and the flat parts of both sides. This layer is only used to increase the adhesion, and the contact area between the layer and the electrode is the same as the contact area between the phase change layer and the electrode.

Further, Dae-Hwan Kang et al. (JAP_p3536_{—}2003) add a heating layer of the same area as the metal plug in the original process, which improves the calorific efficiency to improve the resistance ratio (R-ratio). The proposed thermal conductivity value of it is lower than that of the record layer, but has a R-ratio up to about 10e6 μ Ω cm. Therefore, the amorphous area formed according to the design will cover the lower electrode completely, resulting in a excessively high R-ratio, and higher voltage is required to provide enough current, which will cause the difficulties in circuit design.

Further, a structure is disclosed in the U.S. Pat. No. 6,569,705, in which an adhesion layer is fabricated as a whole, only for increasing the adhesion function. The functional layers disclosed in the U.S. Pat. Nos. 5,534,711, 5,406,509, 5,296,716, etc. are used to provide better electrical contact, but do not have the effect of limiting the current.

On the part of current techniques for developing the phase change memory, the value of R-ratio is either thousands of times as large, or only 2˜3 times, which is not a useful property for the circuit designers. If the resistance variances in high resistance state or amorphous state are taken into consideration, the circumstance of determining 0 and 1 incorrectly may occur. However, the structure and method of the phase change memory disclosed in current techniques haven't proposed efficient solutions for adjusting the R-ratio of the phase change memory.

### SUMMARY OF THE INVENTION

In view of the above problems, the present invention discloses a phase change memory with adjustable resistance ratio, to solve the problems or defects existed in the prior arts.

A phase change memory with adjustable resistance ratio disclosed according to an embodiment of the present invention includes a first electrode, a phase change layer, an interfacial layer and a second electrode; wherein the phase change layer is formed on the first electrode, and a first contact area is defined by the contact section between the first electrode and the phase change layer; the interfacial layer is formed on the phase change layer; the second electrode is formed on the interfacial layer to contact with the interfacial layer so as to define a second contact area which is smaller than the first contact area.

A phase change memory with adjustable resistance ratio disclosed according to the embodiment of the present invention includes a first electrode, a phase change layer, an interfacial layer and a second electrode; wherein the interfacial layer is formed on the first electrode, and a first contact area is defined by the contact section between the first electrode and the interfacial layer; the phase change layer is formed on the interfacial layer; the second electrode is formed on the phase change layer, and a second contact area larger than the first contact area is defined by the contact section between the second electrode and the phase change layer.

The structure disclosed according to the embodiment is very convenient for circuit design under the condition that the R-ratio is adjustable, and is easy to meet the operation condition of the complementary metal-oxide semiconductor (CMOS) in the linear region. Also, the write current can be reduced by the material selection and structure thickness adjustment to improve the performance of the memory property, the process of which is very simple and can reducing the contact area, thus saving the operating power.

The structure disclosed according to the embodiment provides a preferable method to adjust the R-ratios between two states of phase change memory. With an interfacial layer, current can reach the upper electrode via a new path formed by the interfacial layer through passing by the amorphous region the phase change material is formed with the amorphous region. The resistance provided by this new path is a new high resistance (R-high), while the amorphous region only used as a switch of the path. Therefore, the R-ratio can be adjusted by the selection of the material of the interfacial layer and the coating thickness, and under the condition that the R-ratio is adjustable, the convenience of the circuit design can thus be increased. Furthermore, the selection of the material and the structure thickness adjustment can also be used to reduce the write current, so as to reduce the operating power of the memory.

The detailed features and advantages of the present invention will be described in the following detailed description, from the content of which any skilled in the art can understand the techniques of the present invention and can practice the techniques in accordance with it. And any skilled in the art will easily understand the related objects and advantages of the present invention according to the content, claims and drawings disclosed in the present specification.

The description related to the content of the present invention given hereinbefore and the detailed description will be given hereinafter only for illustrating and explaining the principles of the present invention, and the further explanation to the claims of the present invention are provided.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The patent or application file contains at least one drawing executed in color. Copies of this patent or patent application publication with color drawing will be provided by the Office upon request and payment of the necessary fee.

The present invention will become more fully understood from the detailed description given herein below for illustration only for, and thus are not limitative of the present invention, and wherein:

FIG. 1 is a schematic structural view of an embodiment of the phase change memory with adjustable resistance ratio disclosed in the present invention.

FIG. 2 is a schematic structural view of another embodiment of the phase change memory with adjustable resistance ratio disclosed in the present invention.

FIG. 3 is a schematic view of a current path of the phase change memory with adjustable resistance ratio disclosed in the present invention.

FIGS. 4A˜4D are fabrication flow charts of an embodiment of the phase change memory with adjustable resistance ratio disclosed in the present invention.

FIGS. 5A˜5D are fabrication flow charts of another embodiment of the phase change memory with adjustable resistance ratio disclosed in the present invention.

FIGS. 6A˜6C are fabrication flow charts of another embodiment of the phase change memory with adjustable resistance ratio disclosed in the present invention.

### DETAILED DESCRIPTION OF THE INVENTION

The present invention will be described in details in combination with the embodiments in order for further understanding to the objects, structures, features and functions of the present invention.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

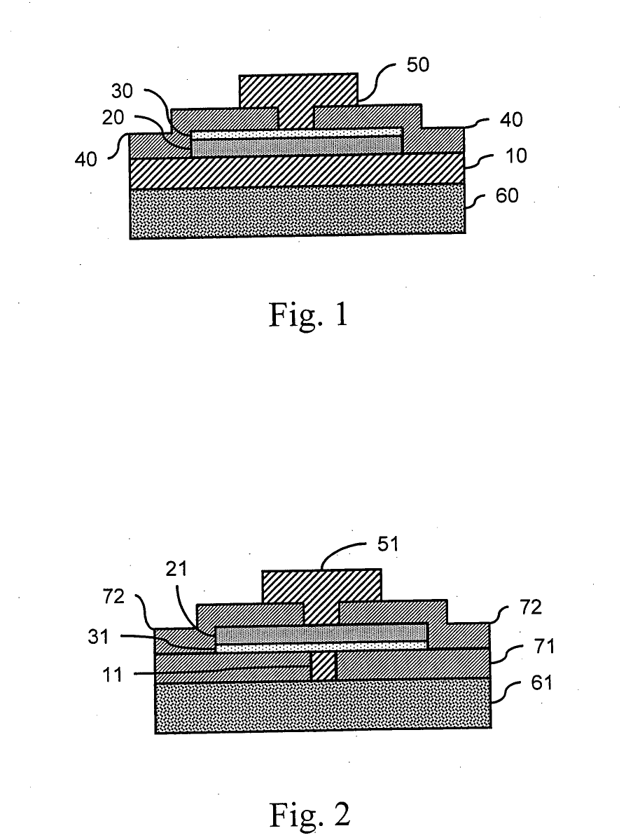

Referring to FIG. 1, which is a phase change memory with adjustable resistance ratio disclosed in the present invention. The phase change memory in this embodiment is composed of a first electrode 10, a phase change layer 20, an interfacial layer 30, a dielectric layer 40 and a second electrode 50.

The phase change layer 20 is formed on the first electrode 10, wherein a first contact area is defined by the contact section (not shown) of the first electrode 10 and the phase change layer 20. The interfacial layer 30 is formed on the phase change layer 20. The dielectric layer 40 is formed on the interfacial layer 30, wherein the dielectric layer 40 is provided with a filling area (which will be described in detail in the fabricating process). The second electrode 50 is formed in the dielectric layer 40 and the filling area to make contact with the interfacial layer to define a second contact area, wherein the first contact area is larger than the second contact area.

The dielectric layer 40 is used to protect the phase change layer 20 and the interfacial layer 30, and is formed generally of nonconductive dielectric materials. And the first electrode 10 and the second electrode 50 are formed with conductive materials such as metal. It can be seen from the figures that, the first contact area defined by the contact section between the first electrode 10 and the phase change layer 20 is larger than the second contact area defined by the contact section between the second electrode 50 and the interfacial layer 30.

Moreover, the first electrode 10 is formed on a substrate 60, wherein said substrate 60 may be a semiconductor substrate and formed in the front-end processes of a transistors of e.g. CMOS or bi-polar. In one embodiment, other electronic elements, e.g. transistor, may be formed therein and contacted with the first electrode 10 to operate a phase change memory formed on the substrate 60.

In the embodiments of FIG. 1 and FIG. 2, the interfacial layer 30 and the phase change layer 20 are defined with the same mask so that they have the same areas; however, the area of the interfacial layer 30 may also be smaller than the area of the phase change layer 20 in actual fabricating, yet still larger than the second contact area defined by the contact section between the second electrode 50 and the interfacial layer 30. In the embodiment of FIG. 1, in order to make the phase change region to be close to the second electrode 50, the material of the interfacial layer 30 should be a material having a R-ratio higher than that of the phase change layer 20 in the crystallized state. In another embodiment, in order to improve the heat dissipation efficiency and to facilitate the formation of the amorphous state, the material of the interfacial layer 30 should be selected to have a thermal conductivity higher than that of the phase change layer 20. The thickness of the interfacial layer 30 cannot be too large, preferably less than 1000 Å, to reduce the span voltage requirement and increase the via resistance. In practical material selection, TiAlN, TiAl₂N, SiC, GeN, α-C, TiSi₂, TiC, TaSiₓ and TiSiN may be selected as the material of the interfacial layer 30.

Referring to FIG. 2, which is another embodiment of a phase change memory with adjustable resistance ratio disclosed in the present invention. The phase change memory in this embodiment is composed of a first electrode 11, a phase change layer 21, an interfacial layer 31, and a second electrode 51.

The interfacial layer 31 is formed on the first electrode 11, wherein a first contact area is defined by the contact section (not shown) between the first electrode 11 and the interfacial layer 31. The phase change layer 21 is formed on the interfacial layer 31. The second electrode 51 is formed on the phase change layer 21, wherein a second contact area larger than the first contact area is defined by the contact section between the second electrode 51 and the phase change layer 21.

Furthermore, the first electrode 11 is formed on a substrate 61, wherein said substrate 61 may be a semiconductor substrate and formed in the front end processes of transistors of e.g. CMOS or bi-polar. In one embodiment, other electronic elements, e.g. transistors, may be formed therein and contacted with the first electrode 11, to operate the phase change memory formed on the substrate 61.

In order to set the first electrode 11 on the substrate 61 preferably, a first dielectric layer 71 is formed between the substrate 61 and the first electrode 11, wherein the first dielectric layer 71 is provided with a filling area (which will be described in the fabricating process), such that the first electrode 11 is formed in the filling area of the first dielectric layer 71. In another embodiment, a second dielectric layer 72 is formed on the phase change layer 21, wherein the second dielectric layer 72 is provided with a filling area (which will be described in the fabricating process), such that the second electrode 51 is formed in the filling area of the second dielectric layer 72. It can be seen from the figures that, the second contact area defined by the contact section between the second electrode 51 and the phase change layer 21 is larger than the first contact area defined by the contact section between the first electrode 11 and the interfacial layer 31.

The first dielectric layer 71 and the second dielectric layer 72 are formed of nonconductive dielectric materials. And the first electrode 11 and the second electrode 51 are formed of conductive materials such as metal.

In the embodiment of FIG. 2, the interfacial layer 31 and the phase change layer 21 are defined with the same mask so that they have the same areas, and the area of the interfacial layer 31 may also be smaller than the area of the phase change layer 21 in practical fabricating, yet still be larger than the first contact area defined by the contact section between the first electrode 11 and the interfacial layer 31. In the embodiment of FIG. 2, in order to make the phase change region to be close to the first electrode 11, the material of the interfacial layer 31 should be selected to have a R-ratio higher than that of the phase change layer 20 in the crystallized state. In another embodiment, in order to improve the heat dissipation efficiency and to facilitate the formation of the amorphous state, the material of the interfacial layer 31 should be selected to have a thermal conductivity higher than that of the phase change layer 21. The thickness of the interfacial layer 31 cannot be too large, preferably less than 1000 Å, to reduce the span voltage requirement and increase the via resistance. In practical material selection, TiAlN, TiAl₂N, SiC, GeN, α-C, TiSi₂, TiC, TaSiₓ and TiSiN may be selected as the material of the interfacial layer 31.

In the embodiments of FIG. 1 and FIG. 2, the phase change layers 20, 21 can present at least two different states, and these states can be referred to as amorphous state and crystallized state. The transition between these states can be triggered selectively according to the change of temperature, wherein the amorphous state and the crystallized state can be distinguished by different R-ratios. For example, the amorphous state usually has a resistance typically higher than that of the crystallized state. Generally, any phase change material may be used, and in some embodiments, thin film chalcogenide alloy, such as GeSbTe is preferred.

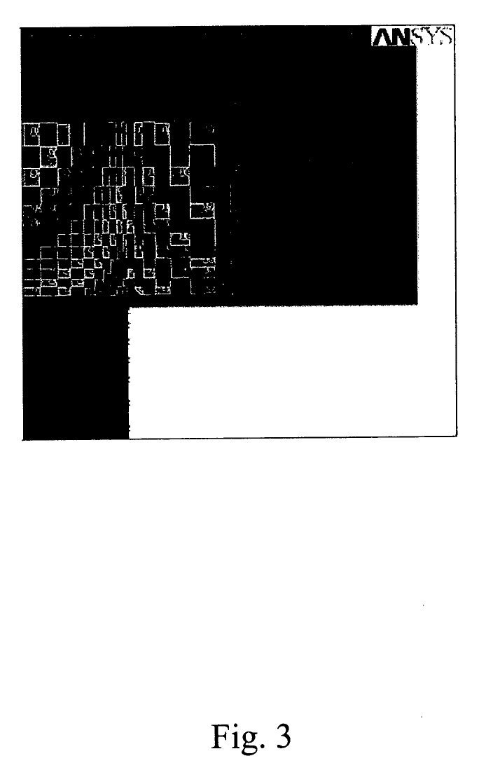

The principle of the present invention will be described below. The phase change memory structure disclosed in the present invention moves the phase change region to an electrode, usually to the electrode with a smaller contact area, for example, the second contact area defined by the contact section between the second electrode 50 and the interfacial layer 30 in the embodiment of FIG. 1, and the first contact area defined by the contact section between the first electrode 11 and the interfacial layer 31 in the embodiment of FIG. 2. The interfacial layer and the phase change layer are defined with the same mask, such that the area of the interfacial layer is the same as that of the phase change layer. Therefore, when phase change is conducted, the high resistance state of the material of the phase change layer becomes a switch in the current path, but not a necessary path, and the current then flows through the interfacial layer and to another electrode, as shown in FIG. 3. The R-ratio can thus be modulated by the interfacial layer material selection and thickness adjustment. The fabricating is thereby much more convenient, and the defect that the amorphous state resistance is too high and easily to drift is thus avoided.

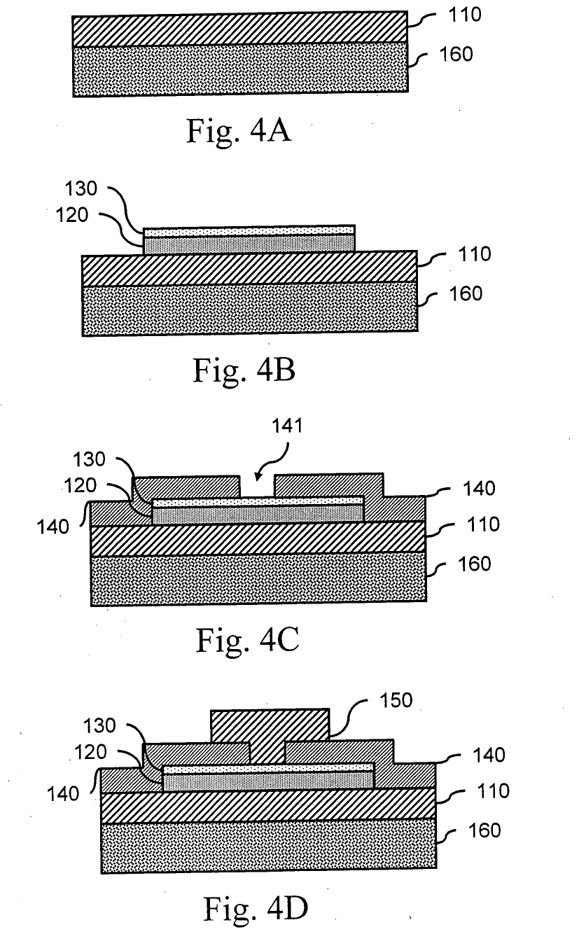

The fabricating flow of the phase change memory disclosed in the above embodiments will be described below. FIGS. 4A˜4D are fabricating flow charts of an embodiment of the phase change memory with adjustable resistance ratio disclosed in the present invention.

First, a substrate 160 is provided, which is formed in the front end process of the CMOS and includes a driving circuit composed of more than one semiconductor devices. A first electrode 110 is then formed on the substrate 160. And the interfacial layer 130 and the phase change layer 120 are defined with the same mask so that they have the same area, wherein the phase change layer 120 is formed on the first electrode 110, and the interfacial layer 130 is formed on the phase change layer 120.

A dielectric layer 140 is then deposed on the interfacial layer 130, and a filling area 141 is formed on dielectric layer 140 by etching, wherein the opening of the filling area 141 is smaller than the first contact area defined by the contact section between the first electrode 110 and the phase change layer 120. A second electrode 150 is finally formed to be partly filled in the filling area 141, such that the second area defined by the contact section between the second electrode 150 and the interfacial layer 130 is smaller than the first contact area defined by the contact section between the first electrode 110 and the phase change layer 120.

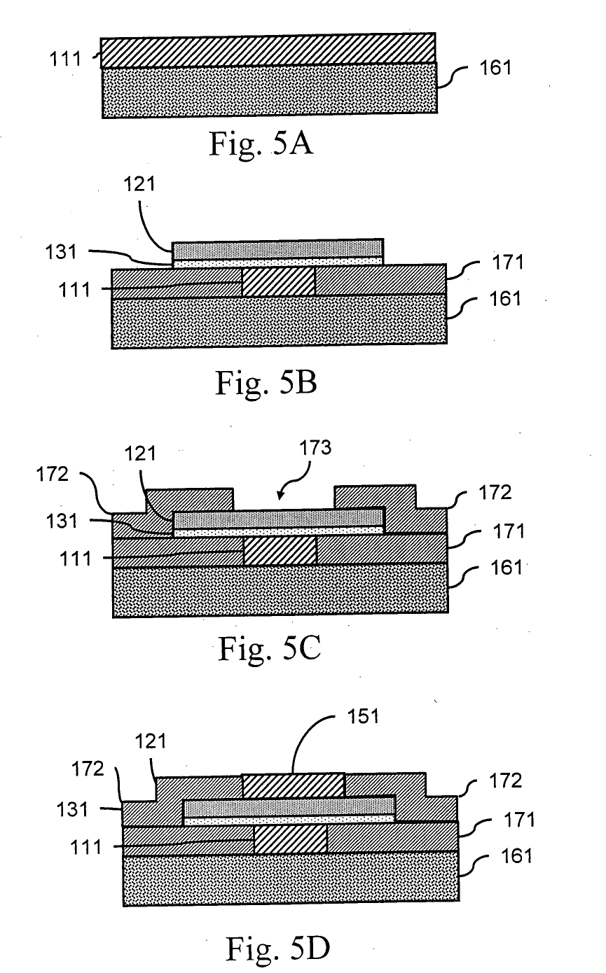

FIGS. 5A˜5D are fabricating flow charts of another embodiment of the phase change memory with adjustable resistance ratio disclosed in the present invention.

First, a substrate 161 is provided, which is formed in the front end process of the CMOS and includes a driving circuit composed of more than one semiconductor device. A first electrode 111 is then formed on the substrate 161. Then the first electrode 111 is etched. A first dielectric layer 171 is then deposited around the first electrode 111, and the surfaces of the first dielectric layer 171 and the first electrode 111 are flattened by chemical mechanical polishing.

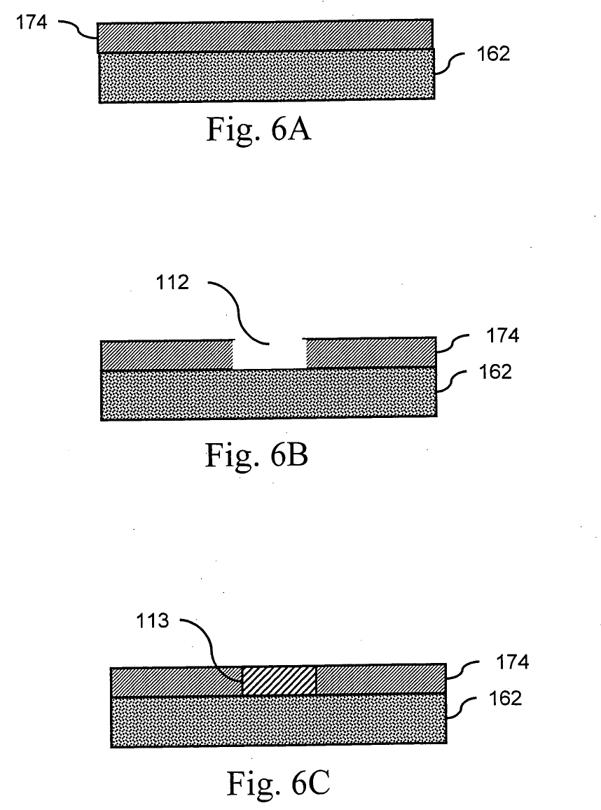

As shown in FIG. 6A˜F6C, a first dielectric layer 174 may also first be formed on a substrate 162, then a first dielectric layer 174 is etched with an opening 112. Next, a first electrode 113 is deposited, which is filled in the opening 112. The portion of the first electrode outside the opening is then flattened by chemical mechanical polishing.

Next, an interfacial layer 131 and a phase change layer 121 is defined with the same mask so that they have the same area, wherein the interfacial layer 131 is formed on the first electrode 110, and the phase change layer 121 is formed on the interfacial layer 131.

A second dielectric layer 172 is then deposited on the interfacial layer 131, and a filling area 173 is formed on the dielectric layer 172 by etching, wherein the opening of the filling area 173 is larger than the first contact area defined by the contact section between the first electrode 111 and the phase change layer 121. Finally, a second electrode 151 is formed, which is partly filled in the filling area 173, such that the first area defined by the contact section between the first electrode 111 and the interfacial layer 131 is smaller than the second contact area defined by the contact section between the second electrode 151 and the phase change layer 121.

The present invention discloses a method and structure capable of adjusting the phase change memory R-ratio value, wherein using such structure and the selection of material properties, a R-ratio range may be adjusted as determined in circuit design, to reduce the changes in the resistance when operating.

According to the phase change memory disclosed in the embodiments, the additional functional layer (i.e. interfacial layer) provides a new current path, such that high resistance and low resistance values can be adjusted by R-ratio and thickness of the functional layer.

According to the phase change memory disclosed in the embodiments, its amorphous region size is not that important, to reduce the highest temperature and elongate the cyclability. Moreover, the phase change memory disclosed in the embodiment can be applied in structures such as spacer structures, T-shape structures, or spacer contact structures and the like.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A phase change memory with adjustable resistance ratio, comprising:
a first electrode;
a phase change layer formed on the first electrode, wherein a first contact area is defined by the contact section between the first electrode and the phase change layer;
an interfacial layer formed on the phase change layer; and
a second electrode formed on the interfacial layer to contact with the interfacial layer so as to define a second contact area, wherein the second contact area is smaller than the first contact area.

2. The memory of claim 1, wherein the first electrode is formed on a substrate.

3. The memory of claim 1, wherein the area of the interfacial layer is larger than the second contact area, but no larger than the area of the phase change layer.

4. The memory of claim 1, wherein the resistance ratio of the interfacial layer is higher than resistance ratio of the phase change layer in the crystallized state.

5. The memory of claim 1, wherein the thermal conductivity of the interfacial layer is higher than the thermal conductivity of the phase change layer.

6. The memory of claim 1, wherein the thickness of the interfacial layer is less than 1000 Å.

7. The memory of claim 1, wherein the interfacial layer is selected form one of the group consisting of TiAlN, TiAl₂N, SiC, GeN, α-C, TiSi₂, TiC, TaSiₓ and TiSiN.

8. The memory of claim 1, further comprising a dielectric layer formed on the interfacial layer, wherein the dielectric layer is formed with a filling area, and the second electrode is formed in the filling area on the dielectric layer.

9. A phase change memory with adjustable resistance ratio, comprising:
a first electrode;
an interfacial layer formed on the first electrode, wherein a first contact area is defined by the contact section between the first electrode and the interfacial layer;
a phase change layer formed on the interfacial layer; and
a second electrode formed on the phase change layer, wherein a second contact area is defined by the contact section between the second electrode and the phase change layer, and the second contact area is larger than the first contact area.

10. The memory of claim 9, wherein the area of the interfacial layer is larger than the first contact area, but no larger than the area of the phase change layer.

11. The memory of claim 9, wherein the resistance ratio of the interfacial layer is higher than the resistance ratio of the phase change layer in the crystallized state.

12. The memory of claim 9, wherein the thermal conductivity of the interfacial layer is higher than the thermal conductivity of the phase change layer.

13. The memory of claim 9, wherein the thickness of the interfacial layer is less than 1000 Å.

14. The memory of claim 9, wherein the interfacial layer is selected form one of the group consisting of TiAlN, TiAl₂N, SiC, GeN, α-C, TiSi₂, TiC, TaSiₓ and TiSiN.

15. The memory of claim 9, wherein the first electrode is formed on a substrate.

16. The memory of claim 9, further comprising a first dielectric layer, wherein the first dielectric layer is formed with a filling area, and the first electrode is formed in the filling area of the interfacial layer.

17. The memory of claim 9, further comprising a second dielectric layer, wherein the second dielectric layer is formed with a filling area, and the second electrode is formed in the filling area on the second dielectric layer.

18. A fabricating method of a phase change memory with adjustable resistance ratio, comprising:
forming a first electrode;
forming a phase change layer on the first electrode, wherein a first contact area is defined by the contact section between the first electrode and the phase change layer;
forming a interfacial layer on the phase change layer; and
forming a second electrode on the interfacial layer to contact with the interfacial layer so as to define a second contact area, wherein the second contact area is smaller than the first contact area.

19. The fabricating method of claim 18, further comprising a substrate, on which the first electrode is formed.

20. The fabricating method of claim 18, wherein the interfacial layer and the phase change layer can be defined by using a same or different mask, such that the area of the interfacial layer is larger than the second contact area, but no larger than the area of the phase change layer.

21. The fabricating method of claim 18, wherein the thickness of the interfacial layer is less than 1000 Å.

22. The fabricating method of claim 18, further comprising a step of forming a dielectric layer on the interfacial layer, wherein the dielectric layer is formed with a filling area, and the second electrode is formed in the filling area on the dielectric layer.

23. A fabricating method of phase change memory with adjustable resistance ratio, comprising:
forming a first electrode;
forming a interfacial layer on the first electrode, wherein a first contact area is defined by the contact section between the first electrode and the interfacial layer;
forming a phase change layer on the interfacial layer; and
forming a second electrode on the phase change layer, wherein a second contact area is defined by the contact section between the second electrode and the phase change layer, and the second contact area is larger than the first contact area.

24. The fabricating method of claim 23, further comprising a substrate, on which the first electrode is formed.

25. The fabricating method of claim 23, wherein the interfacial layer and the phase change layer can be defined by using a same or different mask, such that the area of the interfacial layer is larger than the first contact area, but no larger than the area of the phase change layer.

26. The fabricating method of claim 23, wherein the thickness of the interfacial layer is less than 1000 Å.

27. The fabricating method of claim 23, further comprising a step of forming a first dielectric layer, wherein the first dielectric layer is provided with a filling area, and the first electrode is formed in the filling area of the interfacial layer.

28. The fabricating method of claim 23, further comprising a step of forming a second dielectric layer, wherein the second dielectric layer is formed with a filling area, and the second electrode is formed in the filling area on thee second dielectric layer.
